(19) United States
(12) Patent Application Publication
(10) Pub. No.: US 2020/0286844 A1
(43) Pub. Date: Sep. 10, 2020

(54) SEMICONDUCTOR DEVICE WITH ELECTROPLATED COPPER STRUCTURES

(71) Applicant: Texas Instruments Incorporated, Dallas, TX (US)

(72) Inventors: Keith Edward Johnson, Goleta, CA (US); Nazila Dadvand, Richardson, TX (US)

(21) Appl. No.: 16/292,975

(22) Filed: Mar. 5, 2019

(51) Int. Cl. H01L 23/00; H05K 1/11; H05K 3/10; H05K 3/24

(52) U.S. Cl. CPC H01L 24/11; H05K 2203/1184; H01L 24/05; H01L 24/13; H01L 24/16; H01L 24/48; H05K 1/113; H05K 3/108; H05K 3/243; H01L 2224/03462; H01L 2224/03831; H01L 2224/03848; H01L 2224/05024; H01L 2224/05025; H01L 2224/05082; H01L 2224/05118; H01L 2224/05147; H01L 2224/05166; H01L 2224/05184; H01L 2224/05647; H01L 2224/11462; H01L 2224/11831; H01L 2224/11848; H01L 2224/13024; H01L 2224/13025; H01L 2224/13147; H01L 2224/13082; H01L 2224/16245; H01L 2224/48105; H01L 2224/48245; H05K 2201/0338; H05K 2201/0347; H05K 2203/0723; H05K 2203/1105; H01L 24/03

(57) ABSTRACT

In a described example, a method is described including: depositing a zinc seed layer on a substrate; forming a photoresist pattern on the zinc seed layer, with openings in the photoresist pattern exposing portions of the zinc seed layer; electroplating a copper structure onto the exposed portions of the zinc seed layer; stripping the photoresist; annealing the substrate to form copper/zinc alloy between the copper structure and the substrate; and etching away the unreacted portions of the zinc seed layer.

### TECHNICAL FIELD

This disclosure relates generally to semiconductor devices, and more particularly to packaged semiconductor devices with electroplated copper structures such as copper bumps, copper pillars, or copper leads.

### SUMMARY

In a described example, a method is described, including: depositing a zinc seed layer on a substrate; forming a photoresist pattern on the zinc seed layer, with openings in the photoresist pattern exposing portions of the zinc seed layer; electroplating a copper structure onto the exposed portions of the zinc seed layer; stripping the photoresist, exposing unreacted portions of the zinc seed layer; annealing the substrate to form copper/zinc alloy between the copper structure and the substrate; and etching away the unreacted portions of the zinc seed layer.

### BRIEF DESCRIPTION OF THE DRAWINGS

FIGS. 1A and 1B are cross section views a copper structure on a seed layer with undercut and a copper structure on a seed layer without undercut, respectively.

FIGS. 2A and 2B are a cross section view and top down view respectively of a copper structure on a seed layer with no undercut covering an array of underlying vias.

FIGS. 3A and 3B are a cross section view and a top down view respectively of a copper structure on a seed layer with no undercut on a substrate.

FIGS. 4A-4H are cross sectional views of major steps for forming a copper structure on a seed layer with no undercut.

FIG. 5 is a flow diagram describing FIGS. 4A-4H.

FIGS. 6A and 6B are projection views of a semiconductor wafer and a semiconductor die respectively.

FIG. 6C-6G are cross sectional views of example steps illustrating a method for making packaged dies which contain copper pillars on seed layers with no undercut.

FIG. 6H is a projection view of a quad. flat no lead (QFN) packaged semiconductor die.

FIG. 7 is a flow diagram describing the steps of FIGS. 6A-6G.

FIGS. 8A-8F are cross sectional views of example steps illustrating a method for making packaged dies which contain copper pillars on seed layers with no undercut using flip chip packages.

FIG. 9 is a flow diagram illustrating the method steps shown in FIGS. 8A-8F.

### DETAILED DESCRIPTION

Corresponding numerals and symbols in the different figures generally refer to corresponding parts, unless otherwise indicated. The figures are not necessarily drawn to scale.

As is further described hereinbelow, certain structures and surfaces are described as “perpendicular” to one another. For purposes of this disclosure, two elements are “perpendicular” when the elements are intended to form a 90-degree angle at their intersection. However, the term “perpendicular” as used herein also includes surfaces that may slightly deviate from an angle 90 degrees at the intersection due to manufacturing tolerances. The term “vertical” indicates a direction perpendicular to a horizontal surface, such as the surface of a semiconductor wafer or a printed circuit board lying on a table.

The term “scribe lane” is used herein. A scribe lane is a portion of semiconductor wafer between semiconductor devices. Sometimes in related literature the term “scribe street” is used. Once processing is finished and the semiconductor devices are complete, the semiconductor devices are separated into semiconductor dies by severing the semiconductor wafer along the scribe lanes. This process is referred to as “singulation”. Scribe lanes will be arranged on four sides of a semiconductor device and when singulated from one another, rectangular semiconductor dies are formed. The term “saw streets” is used herein. As used herein, a saw street is a portion of a lead frame strip between lead frames that have semiconductor devices mounted to them. After packaging with mold compound is completed, the packaged semiconductor dies are singulated one from another by cutting through the lead frame strip and the mold compound in the saw streets to form individual semiconductor packages.

The term “electroplated copper structures” is used herein. An electroplated copper structure is a structure of copper formed by electroplating copper on a seed layer. Examples include copper leads on a substrate or a semiconductor device, copper pillars (when capped with solder or other material, copper pillars are sometimes referred to as “copper pillar bumps”) such as used for terminals of a semiconductor device, and copper bumps on a substrate or semiconductor device. Electroplated copper structures are used for leads, traces, and for terminals to make electrical connection to electrical conductors in a substrate. The substrate can be a printed circuit board, a redistribution layer, a laminate or other dielectric material with conductors, a semiconductor wafer or a semiconductor device. Copper pillars and copper bumps are used for electrical terminals for semiconductor dies, for example. Copper rails can be used to provide a power buss or common conductor that may extend across a device, for example.

The term “undercut” is used herein. As used herein, “undercut” is unwanted removal of material lying beneath another structure or layer while being patterned such as by being etched. In the arrangements, a seed layer underlying a conductive structure is etched. Undercut occurs if material previously deposited beneath the conductive structure is removed or partially removed by the etch of the seed layer. In the arrangements, undercut is reduced or eliminated when a seed layer beneath an electroplated conductor structure is etched.

In the arrangements, the problem of undercut of an electroplated copper structure during a seed layer etch is solved by using a zinc seed layer, performing electroplating to form the copper structure on the zinc seed layer, performing a heat treatment to form a zinc-copper alloy at the copper zinc interface which is etch resistant, and subsequently etching the zinc seed layer with an etchant selective to zinc which does not undercut the zinc-copper alloy in the seed layer beneath the copper structure.

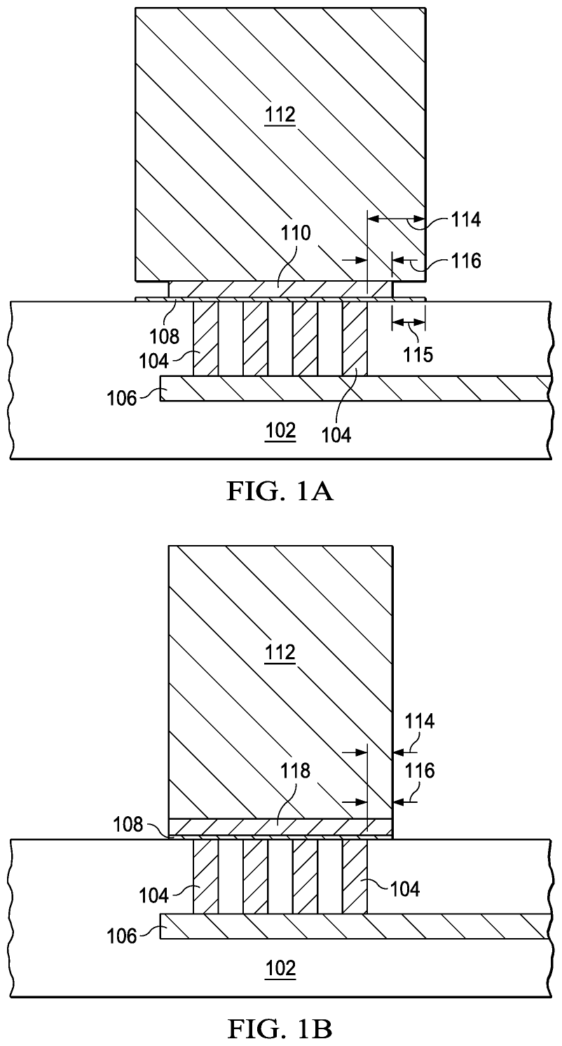

FIGS. 1A and 1B are cross sectional views of a copper structure such as a copper bump, copper pillar or copper lead 112 overlying an array of vias 104 (or contacts). The array of vias 104 electrically connects the copper structure 112 to underlying metal interconnect 106. The metal interconnect 106 and vias 104 are embedded in a substrate 102 which can be a dielectric such as silicon dioxide or silicon nitride or a plastic material such as polyimide or a fiberglass circuit board. The substrate 102 can be a semiconductor wafer, or a nonconductive substrate such as plastic, glass, or ceramic circuit board or interconnect redistribution layer. An adhesion/barrier layer 108 of a metallic material such as titanium tungsten (TiW), titanium nitride (TiN), or tantalum nitride (TaN) covers the surface of the substrate over the vias 104. A seed layer 110 covers the surface of the adhesion/barrier layer 108. The copper structure 112 is electroplated on the seed layer 110.

The copper structures 112 can be formed by electroplating copper onto seed layer 110 that is exposed at the bottom of a trench formed in a photoresist pattern. The photoresist covers portions of the seed layer 110 and prevents the seed layer from being electroplated in areas where no copper is desired. After the copper structure 112 is electroplated, the photoresist pattern is removed. The exposed seed layer 110 surrounding the copper structure 112 (that was prevented from being electroplated by being covered with photoresist) is then etched away. In an example process, the remaining seed layer is removed using a wet etch. Since wet etches are isotropic, the seed layer 110 etches both vertically and horizontally, as is illustrated in FIG. 1A. The horizontal etching undercuts the copper structure 112 in the area labeled 115. When contacts or vias 104 connect the copper structure 112 to underlying interconnect 106, the expected undercut 115 of the seed layer 110 must be taken into account to ensure the minimum copper overlap 116 of the vias 104 is satisfied post processing. The design rule 114 for minimum copper overlap of a via becomes the minimum overlap required for reliability, the minimum spacing design rule 114 is the desired minimum overlap 116 plus the expected undercut 115. Adding extra width for the undercut 115 results in a wider copper structure 112, with a correspondingly increased layout area, resulting in increased substrate size and increased cost.

FIG. 1B illustrates a copper structure 112 on a low undercut seed layer 118. Eliminating the undercut 115 (FIG. 1A) reduces the copper structure 112 overlap of via 104 design rule from an overlap required for reliability (116) plus the expected undercut 115 (FIG. 1A) to only the overlap required for reliability 116 (FIG. 1B). Comparing FIGS. 1A and 1B, the width of a copper structure 112 on a low undercut seed layer 118 (FIG. 1B) is significantly less than the width of a copper structure 112 on a seed layer 110 with undercut (FIG. 1A). This reduces layout area and device cost.

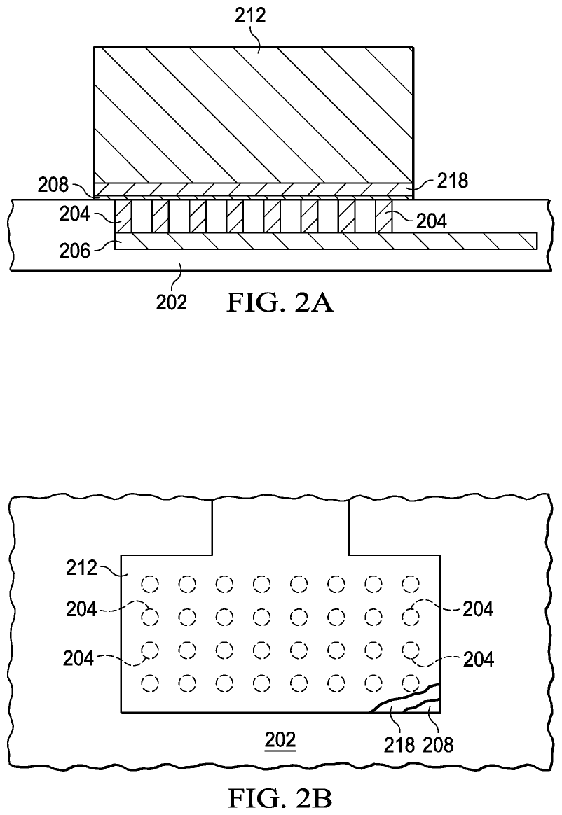

FIGS. 2A and 2B are a cross sectional view and a plan view, respectively, of a copper structure 212 with a low undercut copper/zinc alloy seed layer 218 on an underlying substrate 202. In FIGS. 2A and 2B similar reference labels are used for similar elements as are shown in FIGS. 1A and 1B, for clarity. For example, copper structure 212 in FIGS. 2A and 2B corresponds to copper structure 112 in FIGS. 1A and 1B. The substrate 202 can be a dielectric such as silicon dioxide or silicon nitride or a plastic material such as polyimide or a fiberglass circuit board. An adhesion/barrier layer 208 of a metallic material such as TiW, TiN, or TaN covers the surface of the substrate under the copper structure. The copper/zinc alloy seed layer 218 covers the surface of the adhesion/barrier layer 208. The copper structure 212 covers the copper/zinc alloy seed layer 218.

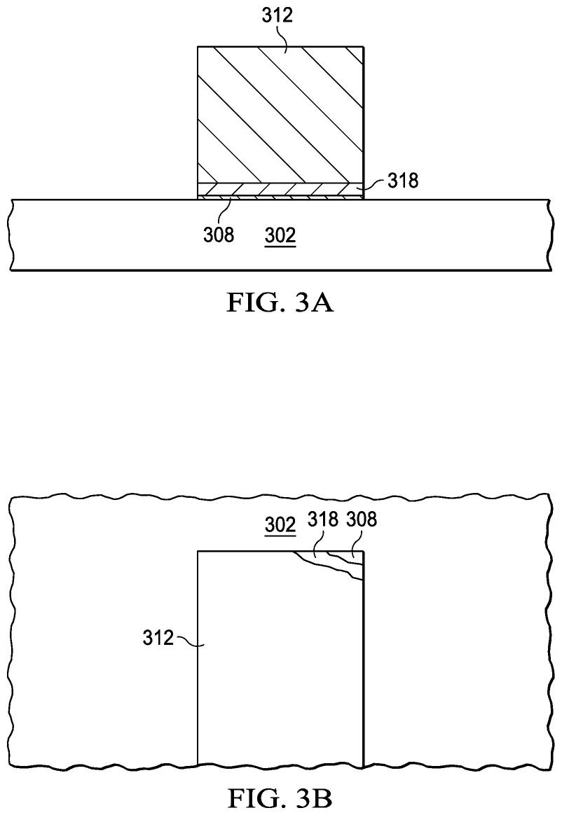

FIGS. 3A and 3B are respectively a cross sectional view and a plan view of copper structure 312 with a low undercut copper/zinc alloy seed layer 318 on an underlying substrate 302. In FIGS. 3A and 3B similar reference labels are used for similar elements as are shown in FIGS. 2A and 2B, for clarity. For example, copper structure 312 in FIGS. 3A and 3B corresponds to copper structure 212 in FIGS. 2A and 2B. The substrate 302 can be a dielectric such as silicon dioxide or silicon nitride or a plastic material such as polyimide or a fiberglass circuit board. An adhesion/barrier layer 308 of a metallic material such as TiW, TiN, or TaN covers the surface of the substrate 302 under the copper structure 312. The copper/zinc alloy seed layer 318 covers the surface of the adhesion/barrier layer 308. The copper structure 312 covers the copper/zinc alloy seed layer 318.

The low undercut copper/zinc alloy seed layer in FIGS. 2A, 2B, 3A, and 3B, eliminates the need to increase the size of copper structure 312 overlap of via (or contact) design rule (see 114, FIG. 1B) that is required to meet electrical reliability specifications. Eliminating the need to add extra width for the undercut results in a narrower copper structure 312 with reduced layout area, resulting in reduced substrate size and reduced cost.

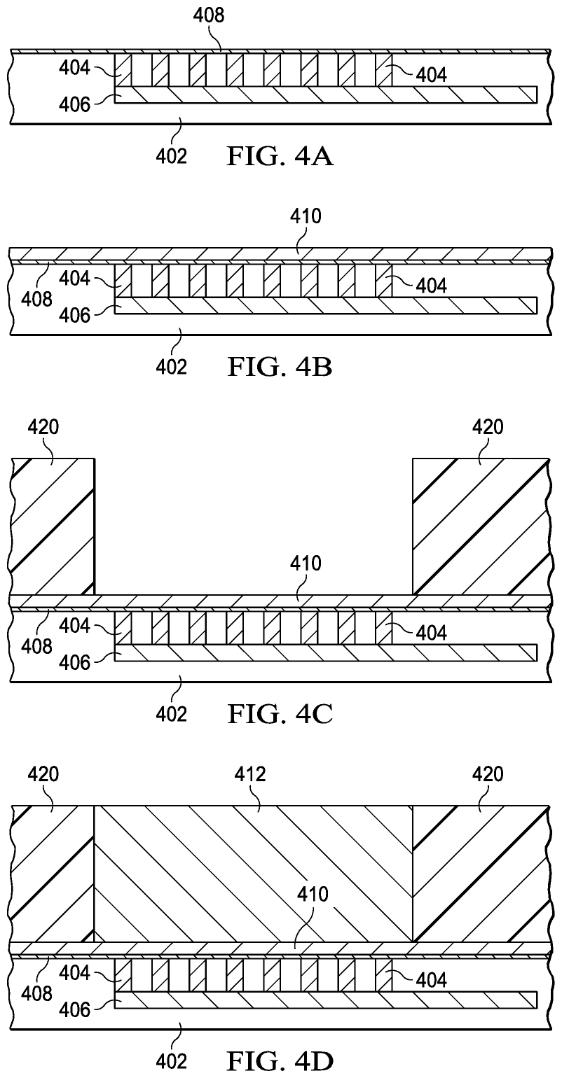

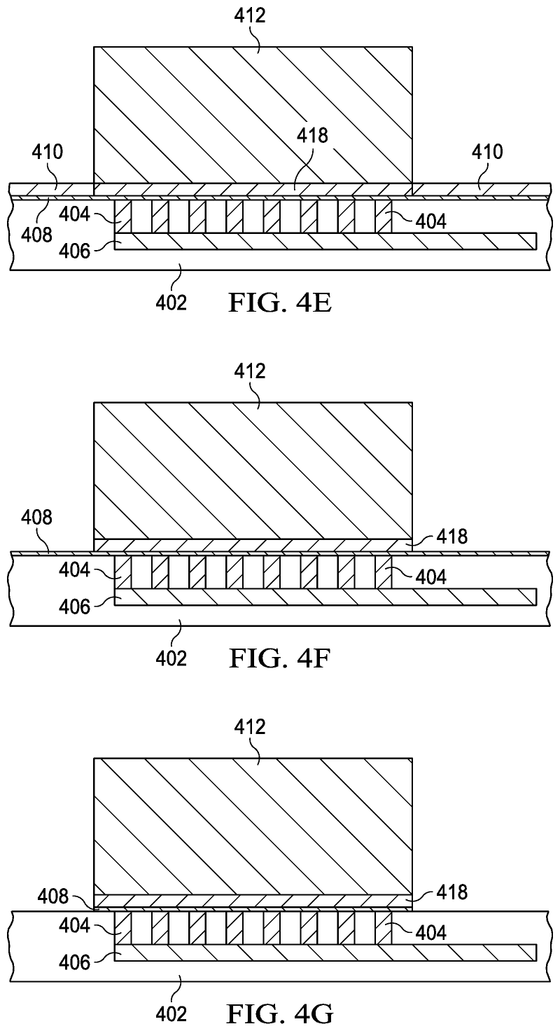

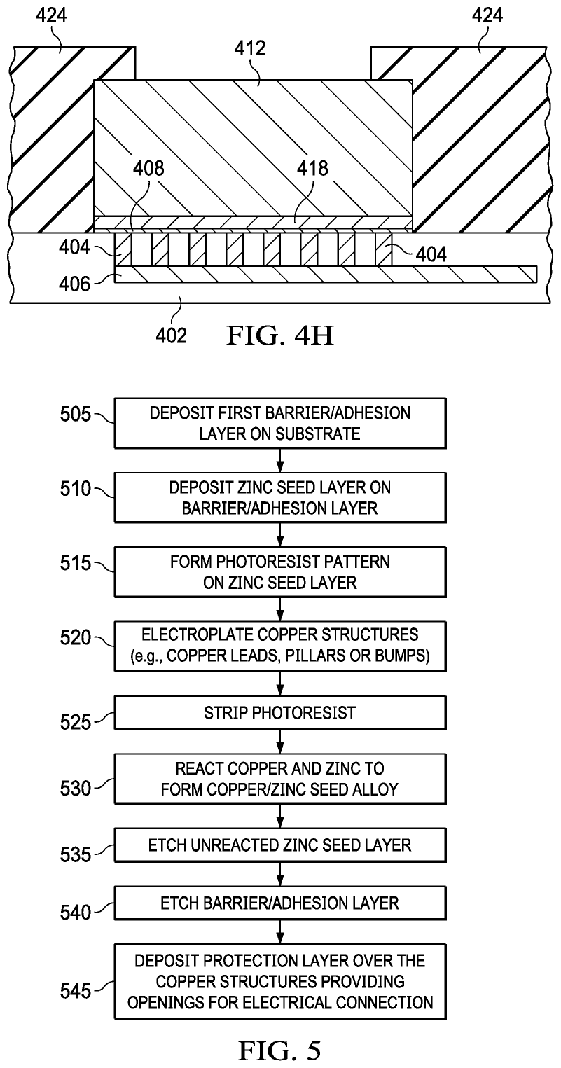

FIGS. 4A through 4H illustrate, in a series of cross sections, a method for forming a copper structure, such as a copper lead, pillar or bump, on a low undercut seed layer. The flow diagram in FIG. 5 summarizes the major process steps depicted in FIGS. 4A through 4H.

FIG. 4A shows a substrate 402 with an embedded interconnect 406. Vias (or contacts) 404 connect the embedded interconnect 406 to the surface of the substrate 402. The tops of the vias 404 are exposed on the surface of the substrate 402. An adhesion/barrier layer 408 is shown deposited over the substrate 402 and the tops of vias 404.

The adhesion/barrier layer 408 is deposited (step 505, FIG. 5) using a physical vapor deposition (PVD) process such as evaporation, sputtering, or atomic layer deposition (ALD). The adhesion/barrier layer 408 can be a metal-containing material such as titanium tungsten (TiW), tantalum nitride (TaN), or titanium nitride (TiN). The adhesion/barrier layer can have a thickness in the range of about 0.1 μm to 1 μm. In an arrangement the adhesion/barrier layer 408 is TiW with a thickness of 0.5 μm.

In FIG. 4B (step 510 in FIG. 5), a seed layer of zinc 410 is deposited on the adhesion/barrier layer 408 using a PVD process. The zinc seed layer 410 can be deposited with a thickness in the range of 800 nm to 2 μm. In an arrangement the zinc seed layer 410 is sputter deposited with a thickness of 1 μm.

A photoresist pattern 420 is formed on the zinc seed layer 410 in FIG. 4C (step 515 in FIG. 5).

In FIG. 4D, (step 520 in FIG. 5) copper structures, in this example leads 412, are electroplated onto the zinc seed layer 410 exposed in openings in the photoresist pattern 420. The thickness of the copper structure 412 may be determined in part by the current carrying requirements of the electrical device.

FIG. 4E shows the structure with the photoresist pattern 420 removed (step 525 in FIG. 5) and with the structure annealed (step 530) to form a copper/zinc alloy seed layer 418 between the copper structure 412 and the adhesion/barrier layer 408. The anneal (step 530) can be performed in an inert atmosphere such as nitrogen or helium for a time between about 1 minute and 30 minutes and at a temperature between about 150° C. and 400° C. The time and temperature can be adjusted to ensure the zinc seed layer 410 fully reacts with the overlying the copper structure 412 to fully convert the zinc to a copper/zinc alloy 418. In an arrangement the anneal was performed for 3 minutes at 180° C. The copper/zinc alloy 418 does not etch in the etchant that will be used to remove the zinc seed layer 410 or the etchant that will be used to remove the adhesion/barrier layer 408 (described hereinbelow). These etches therefore do not form an undercut (115, FIG. 1A) along the edge of the copper structure 412.

In FIG. 4F (step 535 in FIG. 5) a dilute acid such as dilute HF, dil-HCl, or dil-H₂SO₄ is used to remove the unreacted zinc seed layer 410 on the substrate 402 adjacent to the copper structure 412. The copper/zinc alloy 418 is impervious to the dilute acid so little to no undercut of the copper structure 412 occurs. In an application, the undercut is 5% or less than the thickness of the copper/zinc alloy 418. Since an additional width does not have to be added to the copper structure 412 to form an overlap of via 404 design rule to meet reliability requirements, the width of the copper structure 412 can be reduced and the area required for layout is reduced. Alternatively, for a given width of the copper structure, additional vias 404 can be formed as the vias can be placed nearer the edges of the copper structure (lead 412), lowering resistance for the completed arrangement without increasing area.

In FIG. 4G, (step 540) an etching solution such as dilute hydrogen peroxide (H₂O₂) is used to etch away the adhesion/barrier layer 408. In an arrangement, the adhesion/barrier layer is TiW, and the etchant is a 30% solution of H₂O₂. The H₂O₂ does not etch the copper structure 412 or the copper/zinc alloy 418 so the width of the lead is not reduced by the etch and no undercut of the lead 412 is created by this etch.

In FIG. 4H, (step 545) a protective overcoat layer (PO) of a dielectric such as silicon dioxide, silicon nitride, or polyimide is deposited on the surface of the substrate 402 and the copper structures 412. Openings in the PO 424 are then formed to make possible electrical contact to the lead 412, such as bond wires used during packaging. This can be done using a photoresist, pattern and etch process on the PO layer 424.

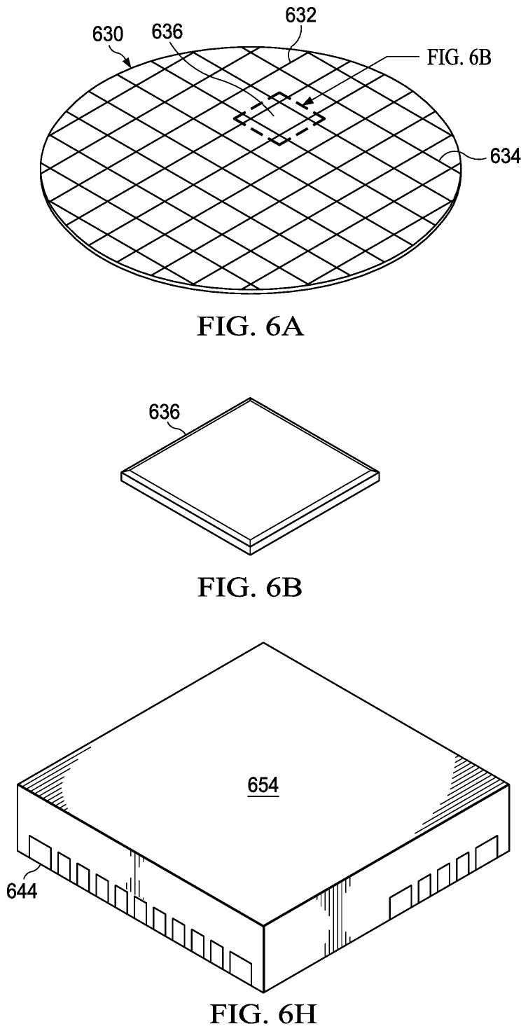

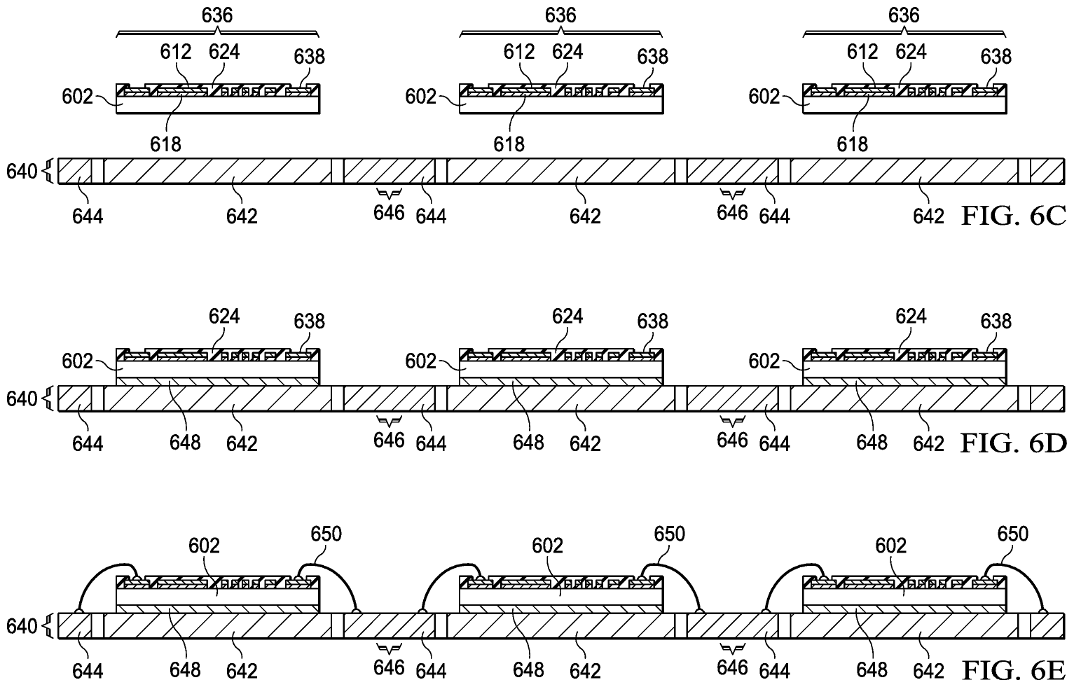

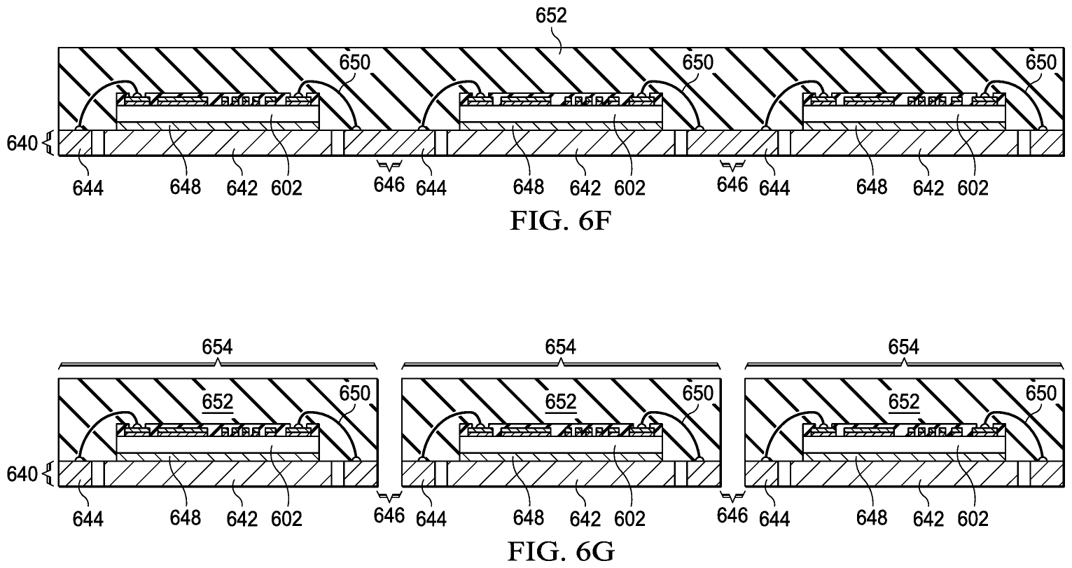

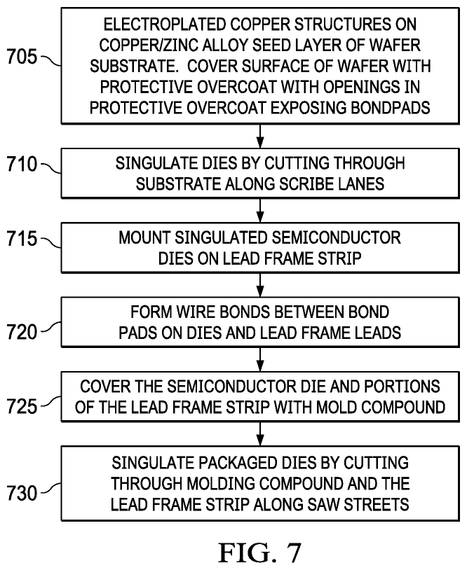

FIGS. 6A-6G illustrate the major steps in the manufacture of a packaged electronic device with copper structures on low undercut copper/zinc alloy. In FIGS. 6A-6G similar reference labels are used for similar elements shown in FIG. 1A, for clarity. For example, substrate 602 in FIGS. 6A-6G corresponds to substrate 102 in FIG. 1A. The flow diagram of FIG. 7 is a description of the corresponding method steps.

FIG. 6A shows a semiconductor device wafer 630 whose surface is covered with semiconductor device dies 636. Horizontal scribe lanes 632 (as portrayed in FIG. 6A) and vertical scribe lanes 634 separate each die 636 from adjacent dies. Copper structures 612 (FIG. 6C) such as copper leads, copper pillars or copper bumps on copper/zinc alloy seed layer 618 on the surface of the dies 636 are covered with a protection layer 624. (See Step 705, FIG. 7). In this example application, the entire surface of the substrate 602 and copper structures 612, except for bondpads 638, is covered with the protection layer 624.

FIG. 6B (step 710) is an expanded view of one of the singulated dies 636, obtained by cutting through a semiconductor wafer along the scribe lanes and removing one die 636 from the remaining dies.

In FIG. 6C, singulated dies 636 are aligned to a die mount pad 642 on a package substrate. In this application the package substrate is a lead frame strip 640, but the package substrate can also be tape-based and film-based package substrates carrying conductors; premolded lead frame (PMLF) strips that combine conductors and mold compound in a structure, ceramic substrates, laminate substrates with multiple layers of conductors and insulator layers; molded interconnect substrates (MIS) that include leads in a mold compound, and printed circuit board substrates of ceramic, fiberglass or resin, or glass fiber reinforced epoxy substrates such as FR4. In a die stacking example, the package substrate can also be another semiconductor device or wafer. In this particular example using a lead frame strip, the lead frame strip is comprised of several individual lead frames (die mount pad 642 plus leads 644) joined together by saw streets 646 and made of lead frame material such as copper or a copper alloy.

In FIG. 6D, the singulated dies 636 (step 715) are mounted on the die mount pad 642 using a bonding agent 648 such as solder or an adhesive, such as a die attach.

In FIG. 6E, bondpads 638 on the dies 636 are electrically connected to leads 644 on the package substrate 640 with a conductor 650 (step 720). In FIG. 6E the conductor 650 is a wirebond. The bondpads 638 can also be copper structures with a low undercut copper/zinc layer formed as described hereinabove.

In FIG. 6F, the dies 636, the conductors 650, and portions of the leads 644 are covered with a mold compound 652 such as a filled epoxy (see step 725 in FIG. 7).

In FIG. 6G, individual packaged dies 654 are singulated (see step 730 in FIG. 7) by cutting through the saw streets 646 on the package substrate 640 (here a lead frame strip.)

FIG. 6H is a projection view of a commercially manufactured quad flat no-lead (QFN) packaged semiconductor device including a semiconductor die.

The copper/zinc layer 618 under the electroplated copper structure 612 has an undercut that is less than 5% the thickness of the copper/zinc layer. In applications, the undercut can be zero or even negative. Elimination of undercut at the edges of copper structures eliminates the need to add extra width to the copper structures to meet reliability requirements for copper structure overlap of contacts or vias. This reduces the copper structure width needed which in turn reduces the area of the electronic device and reduces cost.

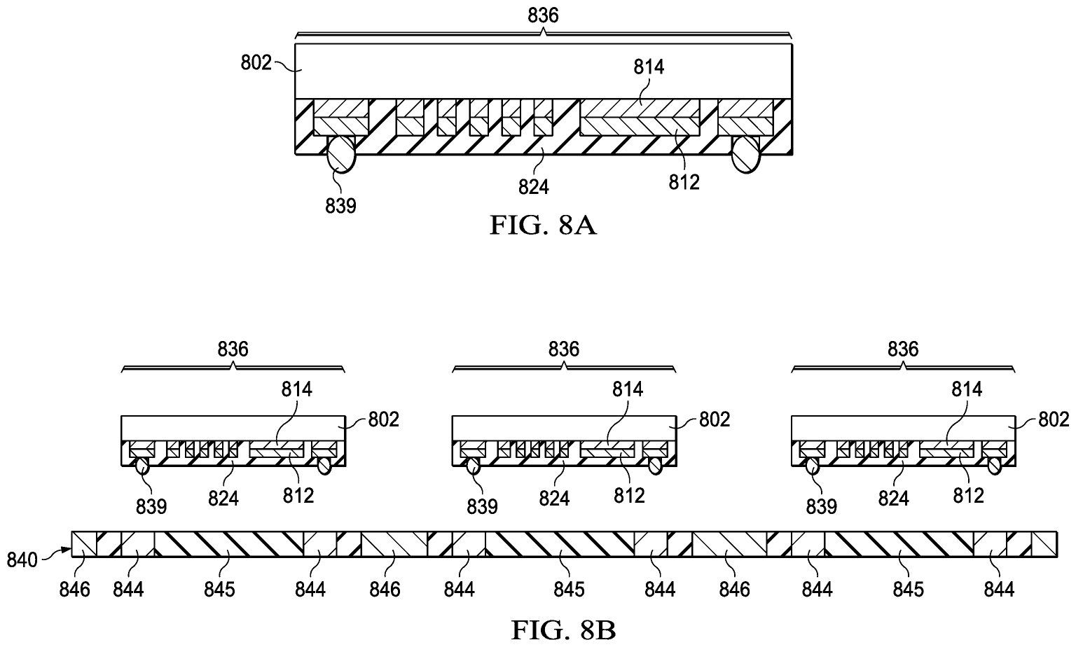

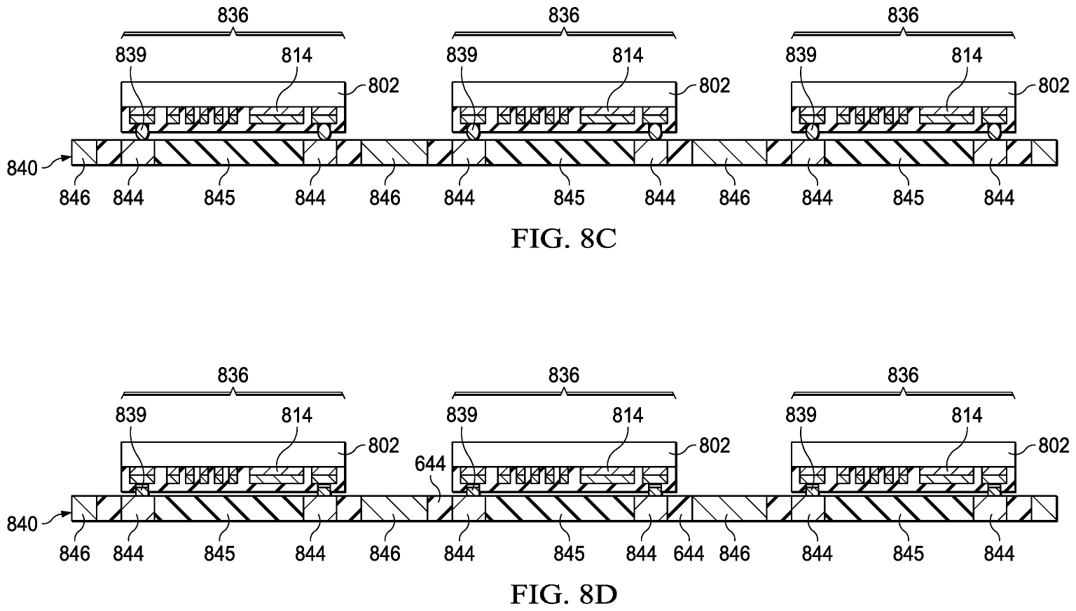

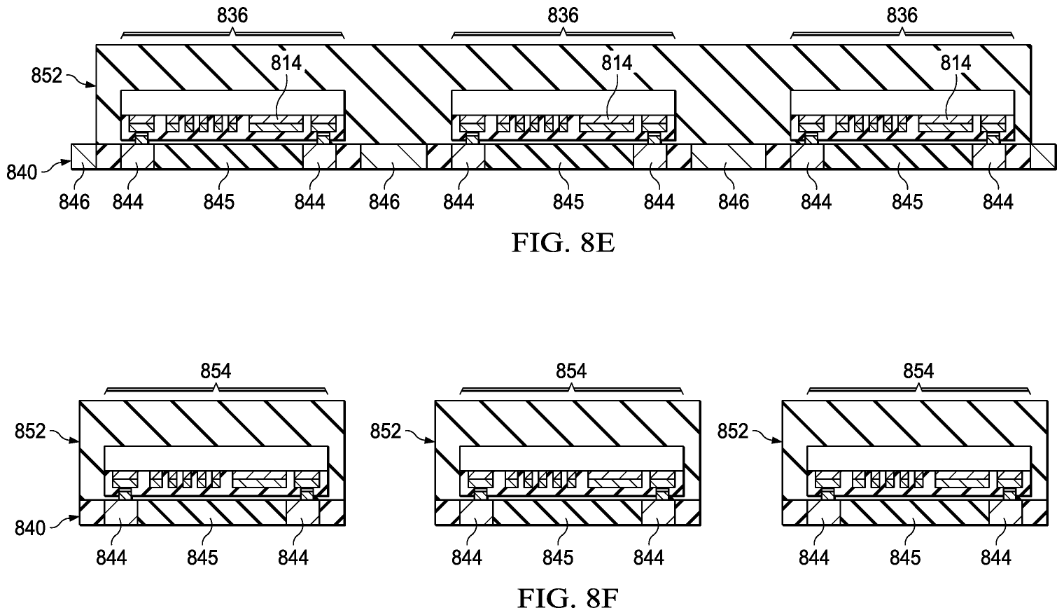

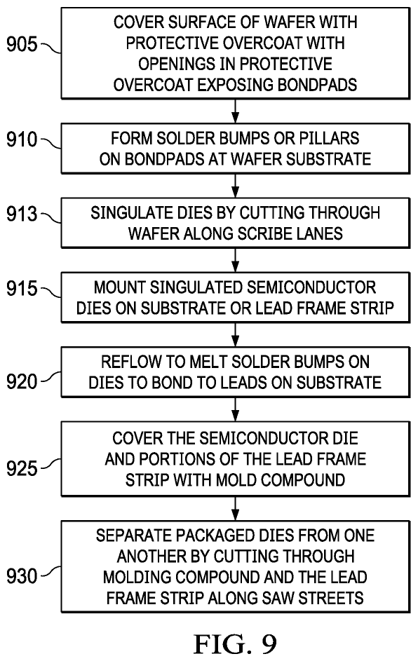

FIGS. 8A-8F illustrate in a series of cross sections major steps needed to flip-chip mount a low undercut semiconductor die to a package substrate, such as a copper lead frame, to form a packaged semiconductor device. FIG. 9 is a flow chart illustrating the method steps shown in the cross sections in FIGS. 8A-8F. For clarity, the reference numerals used in FIGS. 8A-8F are similar to those used in FIG. 6C-6G, for example substrate 802 corresponds to substrate 602.

In FIG. 8A, a singulated semiconductor die 836 is shown after solder bumps 839 (see steps 905, 9110 in FIG. 9) are formed on dies on a substrate in openings in a protective overcoat over copper pillars on the dies 802. The low undercut copper pillars as described hereinabove are formed on the dies 802. The dies are removed from the wafer by cutting through the wafer along scribe lanes and separating the dies from one another. (See step 913 in FIG. 9)

In FIG. 8B, the singulated dies 836 are positioned facing a package substrate 840, such as a lead frame strip, and the solder bumps 839 are positioned over a portion of leads 844 on the package substrate, which can include mold compound 845 or other material between the leads 844. Saw streets 846 are portions of the package substrate 840 between device mounting areas on the substrate 840. In FIG. 8C, the singulated dies 836 are brought into contact with the substrate 840 so that the solder bumps 839 make contact with the lead portions 844. (See step 915 in FIG. 9).

In FIG. 8D, the singulated dies 836 are shown flip-chip mounted to the leads 844 on package substrate 840 after a solder reflow step. The solder balls 839 melt, reflow and bond to the lead portions 844 and form an electrical and physical connection between the copper pillars on the die 802 and the substrate 840. (See step 920 in FIG. 9).

In FIG. 8E, the substrate 840 and the dies 836 are shown after mold compound 852 is applied to cover the dies 836 and a portion of the substrate 840, with portions of the leads 844 remaining uncovered by mold compound 852. The uncovered portions of the leads 844 will form electrical terminals and physical terminals for the completed devices, as described hereinbelow, for use when surface mounting to a system board or module. The mold compound 852 can be thermoset epoxy resin with or without fillers, for example. In one example the thermoset mold compound begins as a solid and is heated to a liquid state, and then is pressed to fill a mold cavity that surrounds the substrate 840 and the dies 836. The mold compound is then cooled and forms a solid package body over the semiconductor dies 836. (See step 925 in FIG. 9). Mold compound can also be used that is liquid at room temperature and can be dispensed over the dies 836 and then cured to a solid state, such as polymers, resins and epoxies.

FIG. 8F illustrates the finished packaged semiconductor devices 854 after the packages are completed by sawing through saw streets 846, and through the overlying mold compound 852, to form singulated flip-chip packaged semiconductor devices 854. In this example the packages shown are quad flat no-lead (QFN) packages, other packages such as small outline no-lead (SON) and leaded and no-lead packages of various types can also be used with the arrangements. (See step 930 in FIG. 9).

Modifications are possible in the described arrangements, and other alternative arrangements are possible within the scope of the claims.

What is claimed is:

1. A device, comprising:
a substrate;
a zinc copper layer between a copper structure and the substrate; and
an undercut of the zinc copper layer beneath the copper structure that is less than 5% a thickness of the zinc copper layer.

2. The device of claim 1, wherein the zinc copper layer is a copper/zinc alloy.

3. The device of claim 2, wherein the zinc copper layer has a thickness between 800 nm and 2 μm.

4. The device of claim 1, wherein the zinc copper layer is on an adhesion/barrier layer covering the substrate.

5. The device of claim 4, wherein the adhesion/barrier layer is one selected from a group consisting essentially of: titanium/tungsten, titanium nitride, and tantalum nitride.

6. The device of claim 1, wherein the zinc copper layer is a copper/zinc alloy on a titanium/tungsten adhesion/barrier layer covering the substrate.

7. The device of claim 1, wherein the substrate is a semiconductor die.

8. The device of claim 7 further comprising:
the semiconductor die mounted on a package substrate;
the semiconductor die and a portion of the package substrate covered with mold compound; and
the mold compound covered semiconductor die and the package substrate forming a packaged semiconductor device.

9. The device of claim 1, wherein the substrate is a redistribution layer.

10. The device of claim 1, wherein the substrate is a printed circuit board.

11. A packaged semiconductor device, comprising:
a semiconductor die bonded to a package substrate, the semiconductor die having copper structures formed on a device side surface of the semiconductor die; and
a copper/zinc alloy layer between the copper structures and the device side surface;
an undercut of the copper/zinc alloy layer beneath the copper structures less than 5% a thickness of the copper/zinc alloy layer; and
mold compound covering the semiconductor die and a portion of the package substrate.

12. The device of claim 11, wherein the copper/zinc alloy layer has a thickness between 800 nm and 2 μm.

13. The device of claim 11, wherein the package substrate is a semiconductor wafer.

14. The device of claim 11, wherein at least some of the copper structures of the semiconductor die are coupled to leads on the package substrate by wire bonds.

15. The device of claim 11, wherein at least some of the copper structures of the semiconductor die are coupled to leads on the package substrate by solder.

16. A method for making a copper structure, comprising:
depositing a zinc seed layer on a substrate;
forming a photoresist pattern on the zinc seed layer, with openings in the photoresist pattern exposing portions of the zinc seed layer;
electroplating a copper structure onto the exposed portions of the zinc seed layer;
annealing the substrate to form copper/zinc alloy between the copper structure and the substrate;
stripping the photoresist, exposing unreacted portions of the zinc seed layer; and
etching away the unreacted portions of the zinc seed layer.

17. The method of claim 16, wherein a thickness of the zinc seed layer is between 800 nm and 2 μm.

18. The method of claim 16, and further comprising depositing an adhesion/barrier layer between the substrate and the zinc layer, wherein the adhesion/barrier layer is titanium/tungsten.

19. The method of claim 16, wherein the anneal is performed in an inert atmosphere between 1 minute and 30 minutes at a temperature between about 150° C. and 400° C.

20. The method of claim 16, wherein the depositing the zinc seed layer comprises physical vapor deposition (PVD).

21. The method of claim 16, wherein the unreacted zinc seed layer is etched away with dilute acid.

22. The method of claim 16, wherein the substrate is a semiconductor wafer.
